(19) United States
(12) Patent Application Publication
(10) Pub. No.: US 2011/0228606 A1
(43) Pub. Date: Sep. 22, 2011

(54) NONVOLATILE SEMICONDUCTOR MEMORY DEVICE

(76) Inventors: Hiroki MUROTANI, Chigasaki-shi (JP); Toshifumi MINAMI, Yokohama-shi (JP)

(21) Appl. No.: 13/050,687

(22) Filed: Mar. 17, 2011

(30) Foreign Application Priority Data
Mar. 19, 2010 (JP) 2010-064749

(51) Int. Cl. G11C 16/04

(52) U.S. Cl. 365/185.11

(57) ABSTRACT

According to one embodiment, a nonvolatile semiconductor memory device comprises a first block, a second block, a storage circuit, a controller. A first block comprises a first select gate and a first word line. A second block comprises a second select gate and a second word line. A storage circuit configures to store first data concerning a voltage to be applied to the first select gate, and second data concerning a voltage to be applied to the second select gate. A controller configures to control the voltages to be applied to the first select gate and the second select gate. The controller applies, in a write operation, a first voltage to the first select gate based on the first data, and a second voltage different from the first voltage to the second select gate based on the second data.

### CROSS-REFERENCE TO RELATED APPLICATIONS

This application is based upon and claims the benefit of priority from Japanese Patent Application No. 2010-064749, filed Mar. 19, 2010; the entire contents of which are incorporated herein by reference.

### FIELD

Embodiments described herein relate generally to a nonvolatile semiconductor memory device, and are applied to, e.g., the control of a write operation in a NAND flash memory.

### BACKGROUND

The cell arrangement of even-numbered block [Even Blk] and odd-numbered block [Odd Blk] in a memory cell array in a NAND flash memory is mirror-symmetrical in the bit-line direction. That is, in two blocks adjacent to each other in the bit-line direction, word lines are mirror-symmetrically assigned the same numbers with the drain contacts or source contacts being sandwiched between them. The write voltage is regulated in accordance with this word-line assignment.

Due to the influence of “coma” as a process factor, however, the word-line widths (in the memory cell transistor gate length direction) cannot be made uniform. Therefore, even word lines assigned the same numbers have different dimensions for each even-numbered block and each odd-numbered block. Also, coupling changes in accordance with this dimensional difference, and the write characteristics vary. Accordingly, the regulation of the write voltage cannot be optimized for each even-numbered block and each odd-numbered block, and the write characteristic reliability decreases.

By contrast, in patent reference 1, individually optimally regulated write voltages are applied to a first word line in an even-numbered block, and to a second word line in an odd-numbered block, which is assigned the same number as that of the first word line. That is, the write voltage is regulated respectively for even-numbered block (Even Blk) and odd-numbered block (Odd Blk).

On the other hand, the same problem arises in select gates. That is, a drain-side select gate and source-side select gate in even-numbered block (Even Blk) and each odd-numbered block (Odd Blk) are mirror-symmetrically disposed. Due to the influence of “coma”, therefore, the width (in the select transistor gate length direction) of the drain-side select gate connected to a bit line changes in each of blocks adjacent to each other in the bit-line direction. In addition, the coupling characteristics also change because the dimensions of word lines assigned the same number and adjacent to these drain-side select gates are different. Consequently, the characteristic of a select transistor changes from one block to another, and a write error occurs.

### BRIEF DESCRIPTION OF THE DRAWINGS

FIG. 1 is a block diagram of a nonvolatile semiconductor memory device according to each embodiment;

FIG. 2 is a circuit diagram showing an example of a memory cell array shown in FIG. 1;

FIG. 3 is a circuit diagram showing another example of the memory cell array shown in FIG. 1;

FIG. 4 is a plan view showing the memory cell array shown in FIG. 1;

FIG. 5A is a view showing a write operation in a selected string of a NAND flash memory related to each embodiment;

FIG. 5B is a view showing a write operation in an unselected string of the NAND flash memory related to each embodiment;

FIG. 6 is a view showing the write operation of a NAND flash memory according to the first embodiment;

FIG. 7 is a flowchart showing the write operation of the NAND flash memory according to the first embodiment;

FIG. 8 is a view showing the write operation of a NAND flash memory according to the second embodiment;

FIG. 9 is a flowchart showing the write operation of the NAND flash memory according to the second embodiment;

FIG. 10 is a graph showing the relationship between a failure bit count (FBC) and a select gate drain voltage VSGD related to the third embodiment;

FIG. 11 is a view showing the write operation of a NAND flash memory according to the third embodiment; and

FIG. 12 is a flowchart showing the write operation of the NAND flash memory according to the third embodiment.

### DETAILED DESCRIPTION

In general, according to one embodiment, a nonvolatile semiconductor memory device comprises a first block, second block, storage circuit, and controller. The first block includes a first select gate, and a first word line adjacent to one side of the first select gate. The second block is placed adjacent to the first block, and includes a second select gate adjacent to the other side of the first select gate with a first contact line connected to a bit line being sandwiched therebetween, and a second word line adjacent to the second select gate and assigned the same number as that of the first word line. The storage circuit stores first data concerning a voltage to be applied to the first select gate, and second data concerning a voltage to be applied to the second select gate. The controller controls the voltages to be applied to the first select gate and the second select gate. In a write operation, the controller applies a first voltage to the first select gate based on the first data, and a second voltage different from the first voltage to the second select gate based on the second data.

Embodiments will be explained blow with reference to the accompanying drawing. In the drawing, the same reference numerals denote the same parts.

### [Overall Configuration Example]

First, an example of the overall configuration of a nonvolatile semiconductor memory device according to an embodiment will be explained below.

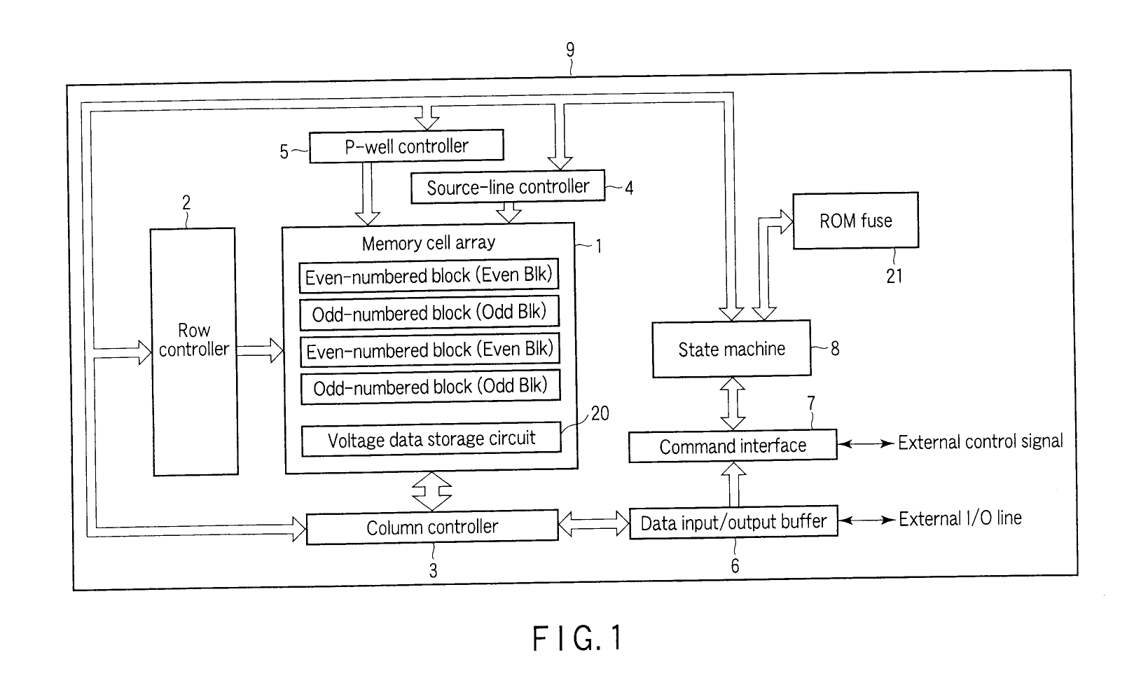

FIG. 1 is a block diagram showing an example of the overall configuration of a NAND flash memory according to this embodiment. As shown in FIG. 1, a NAND flash memory 9 according to this embodiment includes a memory cell array 1, row controller 2, column controller 3, source-line controller 4, p-well controller 5, data input/output buffer 6, command interface 7, and state machine 8.

The memory cell array 1 includes even-numbered blocks (Even Blk), odd-numbered blocks (Odd Blk), and a voltage data storage circuit 20.

As will be described later, each even-numbered block (Even Blk) includes word lines, bit lines, and select gates. Memory cells are arranged at the intersections of the word lines and the bit lines, and select transistors are arranged at the intersections of the select gates and the bit lines.

The odd-numbered blocks (Odd Blk) are arranged adjacent to the even-numbered blocks (Even Blk) with contact lines being sandwiched between them. Each odd-numbered block (Odd Blk) similarly includes word lines, bit lines, and select gates. Memory cells are arranged at the intersections of the word lines and the bit lines, and select transistors are arranged at the intersections of the select gates and the bit lines.

The voltage data storage circuit 20 stores data concerning a voltage to be applied to the select gate in a write operation. The voltage data storage circuit 20 is, e.g., an internal storage circuit (e.g., the even-numbered block (Even Blk)/odd-numbered block (Odd Blk) or a part thereof) of the memory cell array 1. However, it is also possible to use a ROM fuse 21 formed in the NAND flash memory 9 as the voltage data storage circuit 20.

The row controller 2 selects a word line in the memory cell array 1, and applies a voltage necessary for read, write, or erase to the selected word line, under the control of the state machine 8.

The column controller 3 reads data from a memory cell in the memory cell array 11 via a bit line, and detects the state of a memory cell in the memory cell array 1 via a bit line, under the control of the state machine 8. Also, the column controller 3 applies a write control voltage to a memory cell in the memory cell array 1 via a bit line, thereby writing data in the memory cell. The column controller 3 is connected to the data input/output buffer 6 and state machine 8.

The source-line controller 4 applies a necessary voltage to a source line in the memory cell array 1, under the control of the state machine 8.

The p-well controller 5 applies a necessary voltage to a well (e.g., a p-well) formed in a semiconductor substrate of the memory cell array 1, under the control of the state machine 8.

The data input/output buffer 6 is connected to an external I/O line, outputs read data DT read from the memory cell array 1 outside, and outputs externally input write data DT to the command interface 7.

The command interface 7 is connected to an external control signal, and inputs or outputs a control signal under the control of the state machine 8. An example of the external control signal is an Address Latch Enable (ALE) signal.

The state machine 8 controls the operation, e.g., write/read/erase, of the whole NAND flash memory 9. The row controller 2, column controller 3, source-line controller 4, p-well controller 5, and state machine 8 form a write circuit and read circuit.

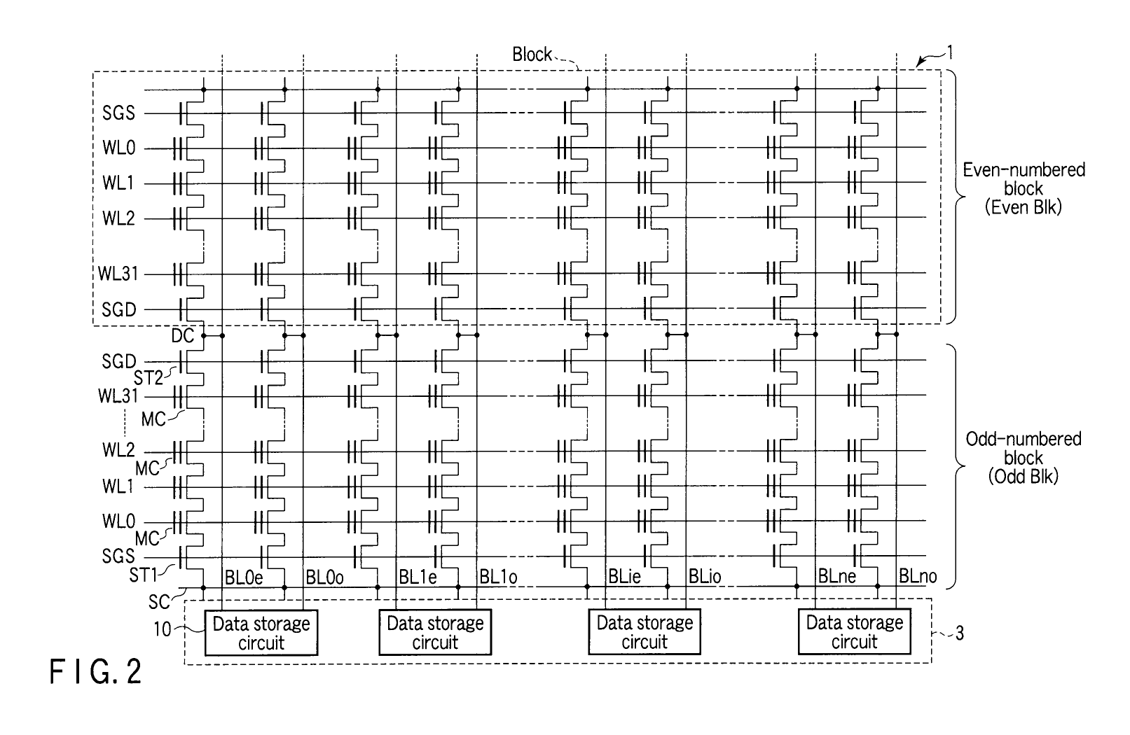

FIG. 2 shows an example of the arrangement of the memory cell array 1 and column controller 3 shown in FIG. 1.

As shown in FIG. 2, NAND strings are arranged in the memory cell array 1. One NAND string includes, e.g., 32 series-connected memory cells MC, and select transistors ST1 and ST2. Select transistor ST2 is connected to a bit line BL0e via a drain contact DC, and select transistor ST1 is connected to a source contact SC. The control gates of the memory cells MC arranged on each row are connected together to a corresponding one of word lines WL0 to WL31. Select transistors ST2 are connected together to a select gate SGD, and select transistors ST1 are connected together to a select gate SGS.

As indicated by the broken lines, the memory cell array 1 includes blocks. Each block includes NAND strings, and data is erased for each block.

Note that FIG. 2 shows two adjacent blocks (an even-numbered block (Even Blk) and odd-numbered block [Odd Blk]). As shown in FIG. 2, these two blocks are mirror-symmetrically arranged with the drain contacts DC being sandwiched between them. That is, in the even-numbered block (Even Blk) and odd-numbered block (Odd Blk), the word lines WL are mirror-symmetrically assigned the same numbers.

The column controller 3 includes data storage circuits 10. Each data storage circuit 10 is connected to a pair of bit lines (BL0e and BL0o), (BL1e and BL1o), . . . , (BLie and BLio), . . . , or (BLne and BLno).

The data storage circuit 10 controls the transfer of read or write data in a read or write operation. In this embodiment, one data storage circuit 10 is formed for two bit lines (e.g., BL1e and BL1o). That is, a read or write operation is executed for memory cells connected to one of two bit lines (e.g., BL1e and BL1o) at the same time.

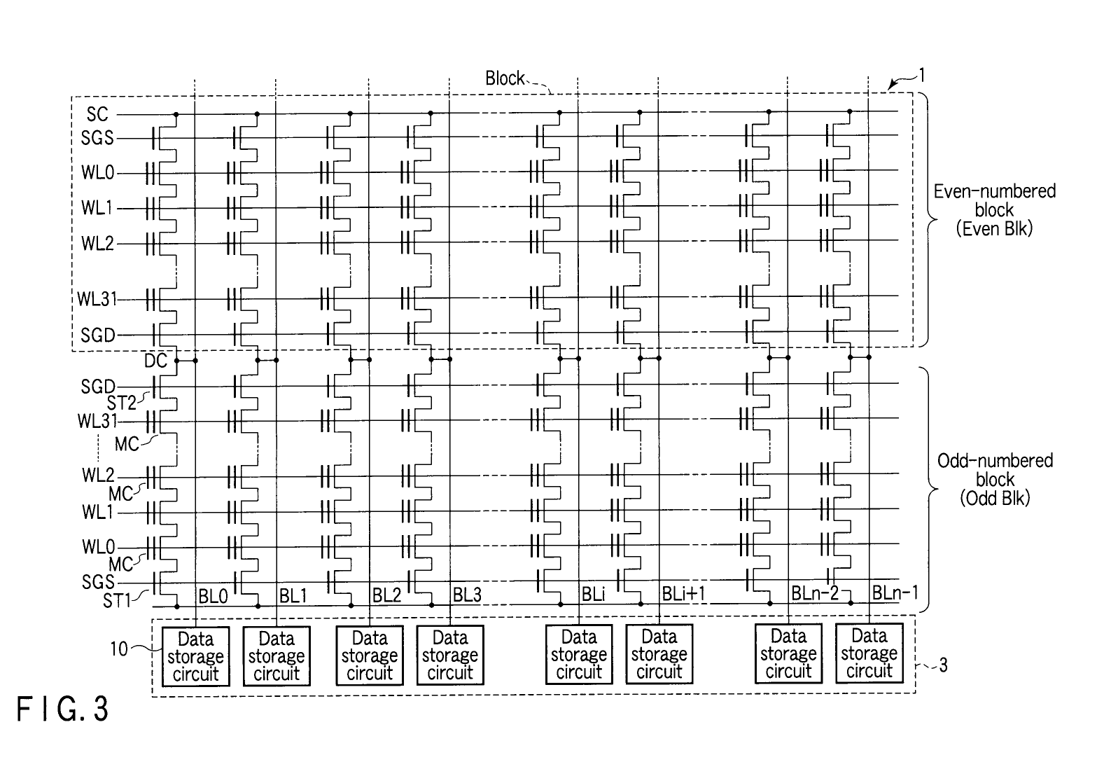

FIG. 3 shows another example of the arrangement of the memory cell array 1 and column controller 3 shown in FIG. 1. In this example as shown in FIG. 3, one data storage circuit 10 is connected to each bit line. Therefore, a read or write operation is performed for memory cells connected to all bit lines at the same time.

Note that the embodiment is applicable to both the arrangements shown in FIGS. 2 and 3.

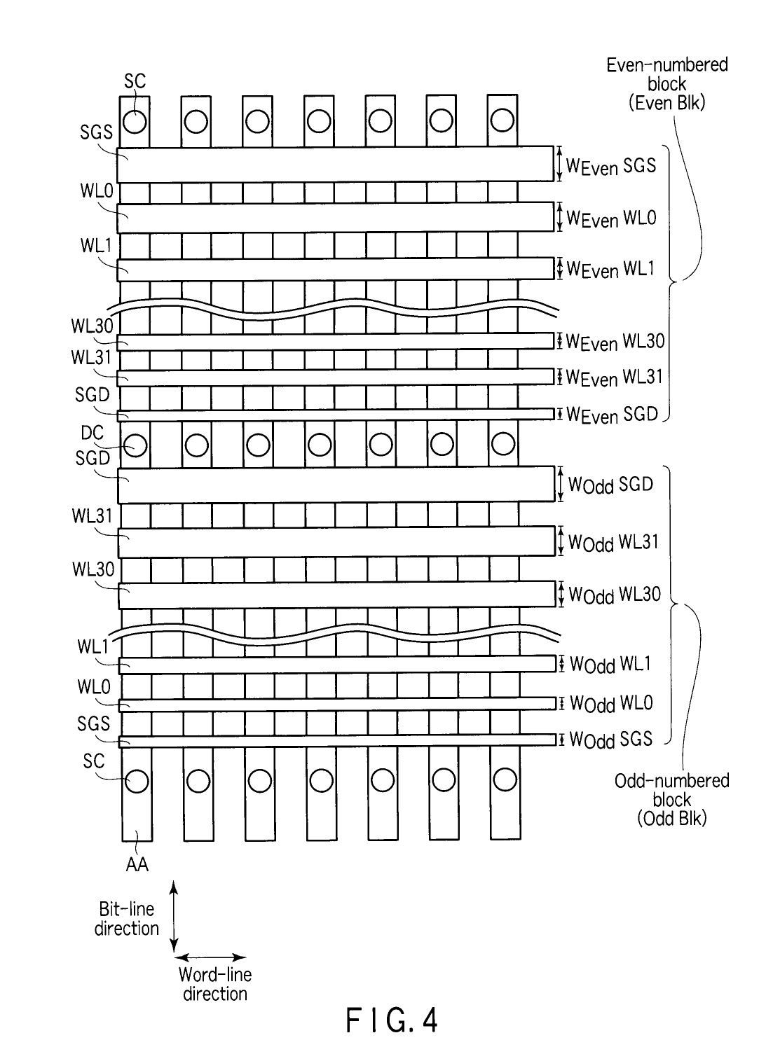

FIG. 4 is a plan view of the memory cell array 1 shown in FIG. 1.

As shown in FIG. 4, even-numbered blocks (Even Blk) and a odd-numbered blocks (Odd Blk) are mirror-symmetrically arranged in the bit-line direction with drain contacts DC or source contacts SC being sandwiched between them.

Each even-numbered block (Even Blk) includes bit lines (not shown), word lines WL0 to WL31, and select gates SGS and SGD.

The word lines WL0 to WL31 are formed by L/S (Line and Space) patterns. More specifically, active areas AA isolated by element isolation regions are formed by L/S along the bit-line direction, and the word lines WL0 to WL31 are formed perpendicularly to the active areas AA.

The select gates SGS and SGD are formed on the two sides so as to sandwich the word lines WL0 to WL31. More specifically, select gate SGS is formed outside, e.g., word line WL0, and select gate SGD is formed outside, e.g., word line WL31.

Each odd-numbered block (Odd Blk) includes bit lines, word lines WL0 to WL31, and select gates SGS and SGD.

The word lines WL0 to WL31 are formed by line-and-space (L/S) patterns. More specifically, active areas AA isolated by element isolation regions are formed by L/S along the bit-line direction, and the word lines WL0 to WL31 are formed perpendicularly to the active areas AA.

The select gates SGS and SGD are formed on the two sides so as to sandwich the word lines WL0 to WL31. More specifically, select gate SGS is formed outside, e.g., word line WL0, and select gate SGD is formed outside, e.g., word line WL31.

The bit lines (not shown) are formed above the word lines WL0 to WL31 in the even-numbered block (Even Blk) and the word lines WL0 to WL31 in the odd-numbered block (Odd Blk), in a direction perpendicular to these word lines. Also, the bit lines are connected to the drain sides of select gates SGD of the even-numbered block (Even Blk) and odd-numbered block (Odd Blk) via the drain contacts DC.

As shown in FIG. 4, the word lines WL0 to WL31 and select gates SGD and SGS in even-numbered block (Even Blk) and odd-numbered block (Odd Blk) are mirror-symmetrically formed. More specifically, in each even-numbered block (Even Blk) and each odd-numbered block (Odd Blk), select gate SGD, word lines WL31, WL30, . . . , WL1, WL0, and select gate SGS are sequentially formed from the drain contact side.

On the other hand, the word-line dimensions (widths) in the bit-line direction are nonuniformly formed in each block due to the influence of “coma” as a process factor. More specifically, dimensions WEvenWL0 to WEvenWL31 of the word lines WL0 to WL31 in the even-numbered block (Even Blk) have relationship WEvenWL0>WEvenWL1> . . . >WEvenWL30>WEvenWL31. Also, dimensions WOddWL0 to WOddWL31 of the word lines WL0 to WL31 in the odd-numbered block (Odd Blk) have relationship WOddWL0<WOddWL1< . . . <WOddWL30<WOddWL31. Therefore, even the word lines WL mirror-symmetrically assigned the same numbers in the even-numbered block (Even Blk) and odd-numbered block (Odd Blk) have different dimensions.

For example, the width WEvenWL0 of word line WL0 in the even-numbered block (Even Blk) is larger than the width WOddWL0 of word line WL0 assigned the same number in the odd-numbered block (Odd Blk) (WEvenWL0>WOddWL0).

Also, the width WEvenWL31 of word line WL31 in the even-numbered block (Even Blk) is smaller than the width WOddWL31 of word line WL31 assigned the same number in the odd-numbered block (Odd Blk) (WEvenWL31<WOddWL31).

Likewise, the dimensions (widths) of the select gates SGD and SGS in the bit-line direction are nonuniformly formed. More specifically, a width WOddSGD of select gate SGD in the odd-numbered block (Odd Blk) is larger than a width WEvenSGD of select gate SGD in the even-numbered block (Even Blk) (WOddSGD>WEvenSGD).

As will be described later, therefore, the state machine 8 shown in FIG. 1 performs control to apply an optimally regulated select gate drain voltage VSGD to select gate SGD, based on data stored in the voltage data storage circuit 20.

### First Embodiment

The write operation of a NAND flash memory according to the first embodiment will be explained below.

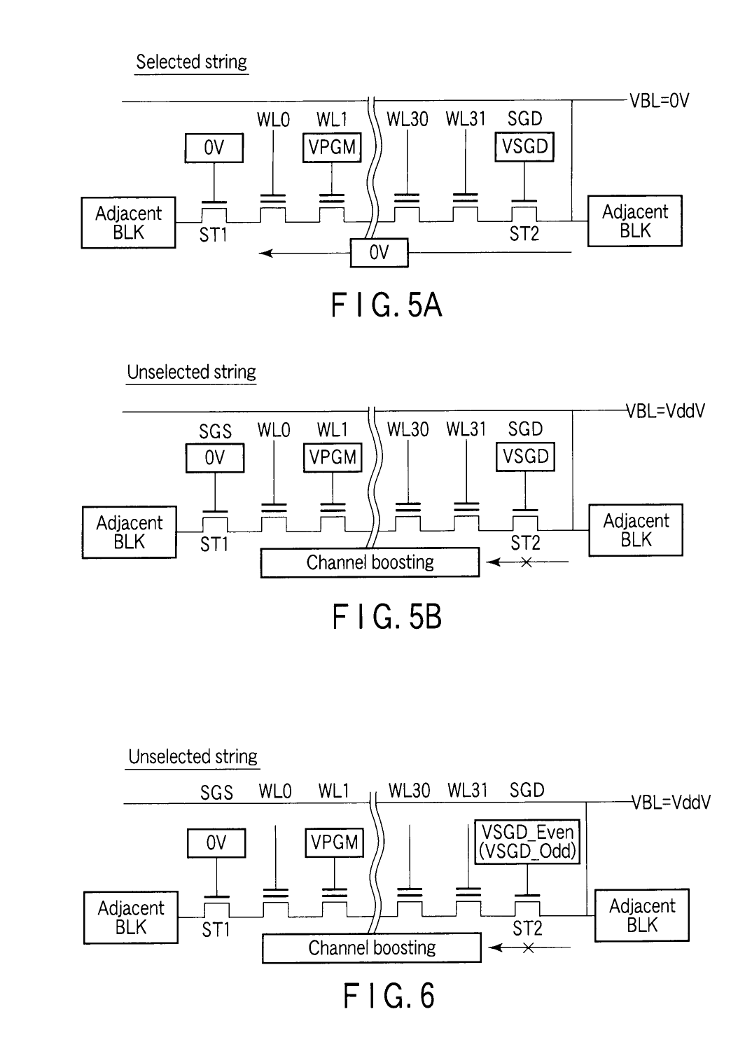

FIGS. 5A and 5B illustrate the write operation of a conventional NAND flash memory related to this embodiment.

In the write operation as shown in FIGS. 5A and 5B, a select gate SGS connected to a select transistor ST1 is set at 0 V, and a select gate drain voltage VSGD is applied to a select gate SGD connected to a select transistor ST2. Also, a write voltage Vpgm is applied to a word line WL1 including a write target cell, and a write pass voltage is applied to word lines WL0, WL30, and WL31 including non-write target cells. In a selected string, data is written in the cell by setting a voltage VBL of a bit line BL at 0 V.

On the other hand, in an unselected string, data is not written in the memory cells by setting voltage VBL of the bit line BL at Vdd (an internal voltage). In this state, select transistor ST2 is cut off by applying an optimum select gate drain voltage VSGD to select gate SGD. This makes it possible not to write data by boosting the channel of each memory cell in the unselected string.

Normally, the characteristic of select transistor ST2 changes from one chip to another. Therefore, select gate drain voltage VSGD has an optimum value pretrimmed for each chip, so as not to perform data write (cause write errors) in memory cells of an unselected string. As described above, however, even in the same chip, the characteristic of select transistor ST2 changes for each even-numbered block (Even Blk) and each odd-numbered block (Odd Blk) even in the same chip, due to the influence of “coma” as a process factor. Accordingly, optimum select gate drain voltage VSGD cannot be applied to select transistor ST2. As a consequence, the channel boosting efficiency decreases, and write errors occur in an unselected string.

To solve this problem, the first embodiment is an example in which select gate drain voltage VSGD is optimally trimmed for each block (each even-numbered block and each odd-numbered block).

FIG. 6 shows the write operation of the NAND flash memory according to this embodiment.

In the write operation as shown in FIG. 6, Vdd is applied to the bit line BL in an unselected string. In addition, an optimum voltage is applied to select gate SGD of each of the even-numbered block (Even Blk) and odd-numbered block (Odd Blk), in order to cut off select transistor ST2. More specifically, an optimally trimmed select gate drain voltage VSGD_Even is applied to select gate SGD of the even-numbered block (Even Blk), and an optimally trimmed select gate drain voltage VSGD_Odd is applied to select gate SGD of the odd-numbered block (Odd Blk). The voltage data storage circuit 20 shown in FIG. 1 stores data of select gate drain voltages VSGD_Even and VSGD_Odd.

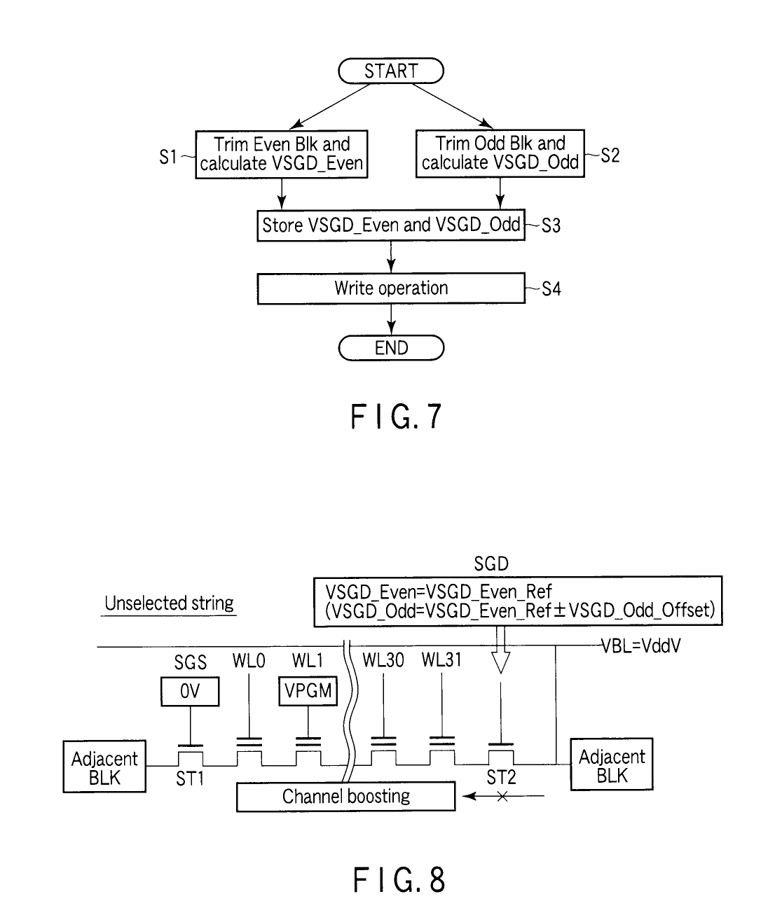

FIG. 7 is a flowchart of the write operation of the NAND flash memory according to this embodiment.

As shown in FIG. 7, in step S1, select gate drain voltage VSGD_Even is trimmed in the even-numbered block (Even Blk). Consequently, voltage VSGD_Even optimum for select transistor ST2 in the even-numbered block (Even Blk) is calculated. Voltage VSGD_Even has a value regulated in accordance with the width WEvenSGD of select gate SGD and the width WEvenWL31 of word line WL31 in the even-numbered block (Even Blk).

On the other hand, in step S2, select gate drain voltage VSGD_Odd is trimmed in the odd-numbered block (Odd Blk). Consequently, voltage VSGD_Odd optimum for the select transistor in the odd-numbered block (Odd Blk) is calculated. Voltage VSGD_Odd has a value regulated in accordance with the width WOddSGD of select gate SGD and the width WOddWL31 of word line WL31 in the odd-numbered block (Odd Blk).

For example, voltage VSGD_Odd and voltage VSGD_Even is trimmed by a die-sort test.

Then, in step S3, the voltage data storage circuit 20 stores data of select gate drain voltage VSGD_Even optimum for the even-numbered block (Even Blk) and select gate drain voltage VSGD_Odd optimum for the odd-numbered block (Odd Blk). The data of each of voltages VSGD_Even and VSGD_Odd is, e.g., 4-bit data.

After that, in step S4, voltages VSGD_Even and VSGD_Odd are read from the voltage data storage circuit 20. As a consequence, the write operation is performed by respectively using the optimum select gate drain voltages VSGD_Even and VSGD_Odd for the even-numbered block (Even Blk) and odd-numbered block (Odd Blk).

### [Effect]

In the above-mentioned first embodiment, the voltage data storage circuit 20 stores the data of voltages VSGD_Even and VSGD_Odd respectively optimally regulated for select gates SGD of the even-numbered block (Even Blk) and odd-numbered block (Odd Blk). In the write operation, the state machine 8 reads the data of voltages VSGD_Even and VSGD_Odd from the voltage data storage circuit 20, and controls the voltage to be applied to select gate SGD of each block. This makes it possible to increase the channel boosting efficiency of memory cells in unselected strings of each block. Accordingly, even when select gates SGD and word lines WL produce dimensional differences in each of even-numbered block (Even Blk) and odd-numbered block (Odd Blk) due to the influence of “coma” as a process factor, write errors to memory cells in unselected strings can be prevented.

### Second Embodiment

The write operation of a NAND flash memory according to the second embodiment will be explained below. In the first embodiment, the voltage data storage circuit 20 individually stores the data of the select gate drain voltages optimum for the even-numbered block (Even Blk) and odd-numbered block (Odd Blk). By contrast, the second embodiment is an example in which the influence of “coma” is canceled by regulating one of the select gate drain voltages of the even-numbered block (Even Blk) and odd-numbered block (Odd Blk) by using the other select drain gate voltage as a reference. Note that in the second embodiment, the same features as those of the above-mentioned first embodiment will be omitted, and the differences will be explained in detail.

FIG. 8 shows the write operation of the NAND flash memory according to this embodiment.

In the write operation as shown in FIG. 8, Vdd is applied to a bit line BL in an unselected string. In addition, optimum voltages are respectively applied to select gates SGD of the even-numbered block (Even Blk) and odd-numbered block (Odd Blk), in order to cut off select transistors ST2. More specifically, an optimally trimmed select gate drain voltage VSGD_Even is applied to select gate SGD of the even-numbered block (Even Blk). On the other hand, a select gate drain voltage VSGD_Odd optimally regulated by using voltage VSGD_Even as a reference is applied to select gate SGD of the odd-numbered block (Odd Blk). Voltages VSGD_Even and VSGD_Odd in this embodiment are respectively indicated by

VSGD_Even=VSGD_Even_Ref

VSGD_Odd=VSGD_Even_Ref±VSGD_Odd_offset

The voltage data storage circuit 20 shown in FIG. 1 stores data (reference data) of select gate drain voltage VSGD_Even Ref, and data (offset data) of VSGD_Odd offset.

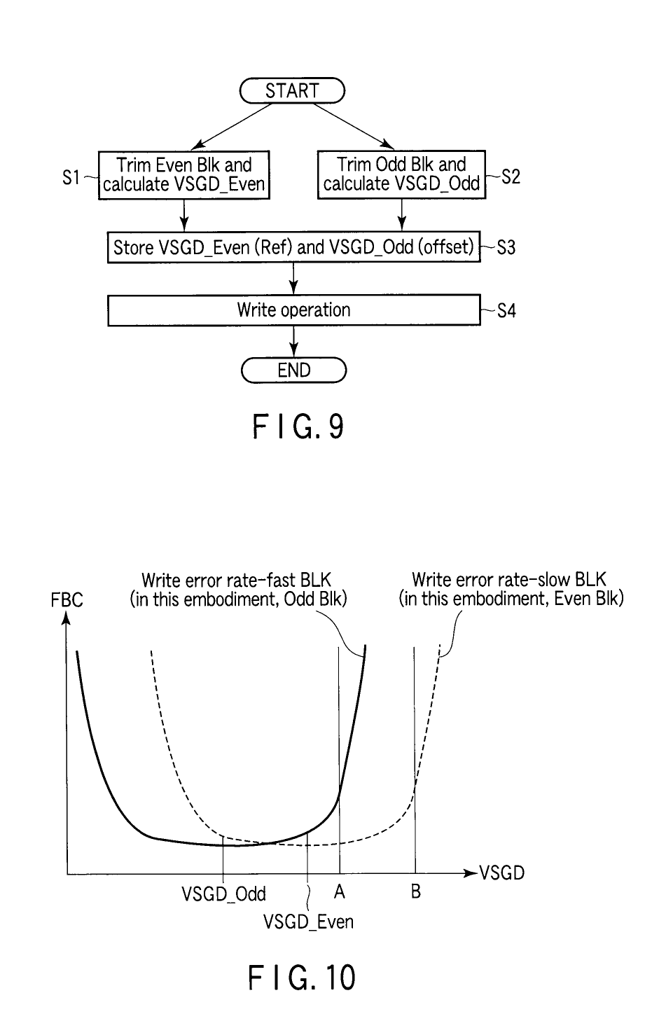

FIG. 9 is a flowchart of trimming of the NAND flash memory according to this embodiment.

As shown in FIG. 9, in step S1, select gate drain voltage VSGD_Even is trimmed in the even-numbered block (Even Blk). Consequently, VSGD_Even optimum for a select transistor of the even-numbered block (Even Blk) is calculated.

On the other hand, in step S2, select gate drain voltage VSGD_Odd is trimmed in the odd-numbered block (Odd Blk). Consequently, VSGD_Odd optimum for a select transistor of the odd-numbered block (Odd Blk) is calculated.

For example, voltage VSGD_Odd and voltage VSGD_Even is trimmed by the die-sort test.

Then, in step S3, the voltage data storage circuit 20 stores data of select gate drain voltage VSGD_Even (VSGD_Even_Ref) optimum for the even-numbered block (Even Blk) as reference data. This data (reference data) of voltage VSGD_Even_Ref is, e.g., 4-bit data.

In addition, the voltage data storage circuit 20 stores, as offset data, data of a difference VSGD_Odd_offset between voltage VSGD_Even (VSGD_Even_Ref) optimum for the even-numbered block (Even Blk) and voltage VSGD_Odd optimum for the odd-numbered block (Odd Blk). This data (offset data) of voltage VSGD_Odd_offset is, e.g., 2-bit data.

After that, in step S5, the data (reference data) of voltage VSGD_Even_Ref and the data (offset data) of voltage VSGD_Odd offset are read from the voltage data storage circuit 20. Thus, the write operation is performed by respectively using the optimum select gate drain voltages VSGD_Even (VSGD_Even_Ref) and VSGD_Odd (VSGD_Even_Ref±VSGD_Odd_offset) for the even-numbered block (Even Blk) and odd-numbered block (Odd Blk).

### [Effects]

The above-mentioned second embodiment can achieve the same effect as that of the first embodiment.

In addition, in this embodiment, select gate drain voltage VSGD_Odd of the odd-numbered block (Odd Blk) is regulated by using select gate drain voltage VSGD_Even of the even-numbered block (Even Blk) as a reference. More specifically, the voltage data storage circuit 20 stores the data of voltage VSGD_Even Ref of the even-numbered block (Even Blk) as reference data, and the data of the difference VSGD_Odd offset between VSGD_Even and VSGD_Odd as offset data. In the write operation, the state machine 8 reads the reference data and offset data, and controls the voltage to be applied to select gate SGD of each block. The reference data and offset data to be stored in the voltage data storage circuit 20 are respectively, e.g., 4-bit data and 2-bit data. When compared to the first embodiment, therefore, the number of bits of the data to be stored in the voltage data storage circuit 20 can be reduced. This makes it possible to reduce the circuit (chip) area.

Note that in this embodiment, the voltage data of the even-numbered block (Even Blk) is used as the reference data. However, the present embodiment is not limited to this, and the voltage data of the odd-numbered block (Odd Blk) may also be used as the reference data. More specifically, the voltage data storage circuit 20 can also store the data of select gate drain voltage VSGD_Odd (VSGD_Odd_Ref) of the odd-numbered block (Odd Blk) as the reference data, and data of a difference VSGD_Even offset between VSGD_Even and VSGD_Odd as the offset data.

### Third Embodiment

The write operation of a NAND flash memory according to the third embodiment will be explained below. The third embodiment is a modification of the second embodiment, and an example in which, among an even-numbered block (Even Blk) and odd-numbered block (Odd Blk), a select gate drain voltage VSGD of one of a write error rate-slow block (Slow Blk) in which write error occur on higher voltage and a write error rate-fast block (Fast Blk) in which write error occur on lower voltage is regulated by using select gate drain voltage VSGD of the other block as a reference, thereby canceling the influence of “coma”.

Note that in this embodiment, an operation when the even-numbered block (Even Blk) is the write error rate-slow block (Slow Blk) and the odd-numbered block (Odd Blk) is the write error rate-fast block (Fast Blk) will be explained. Note also that the same features as those of the first embodiment will be omitted, and the differences will be explained in detail.

FIG. 10 is a graph showing the relationship between a failure bit count (FBC) and select gate drain voltage VSGD related to this embodiment.

As shown in FIG. 10, the FBC increases (a write error occurs) when select gate drain voltage VSGD is changed (e.g., raised) in normal trimming. Select gate drain voltage VSGD is regulated based on the change (increase) in FBC like this.

More specifically, when voltage VSGD is increased in a write error rate-fast block (Fast Blk) (the solid line), the FBC abruptly increases (write errors abruptly increase) near a voltage A. On the other hand, when VSGD is increased in a write error rate-slow block (Slow Blk) (the broken line), the FBC abruptly increases (write errors abruptly increase) near a voltage B larger than voltage A. In this embodiment as described above, voltage VSGD is regulated by judging a write error based on the relationship between the change in FBC and voltages A and B, thereby determining the voltage data.

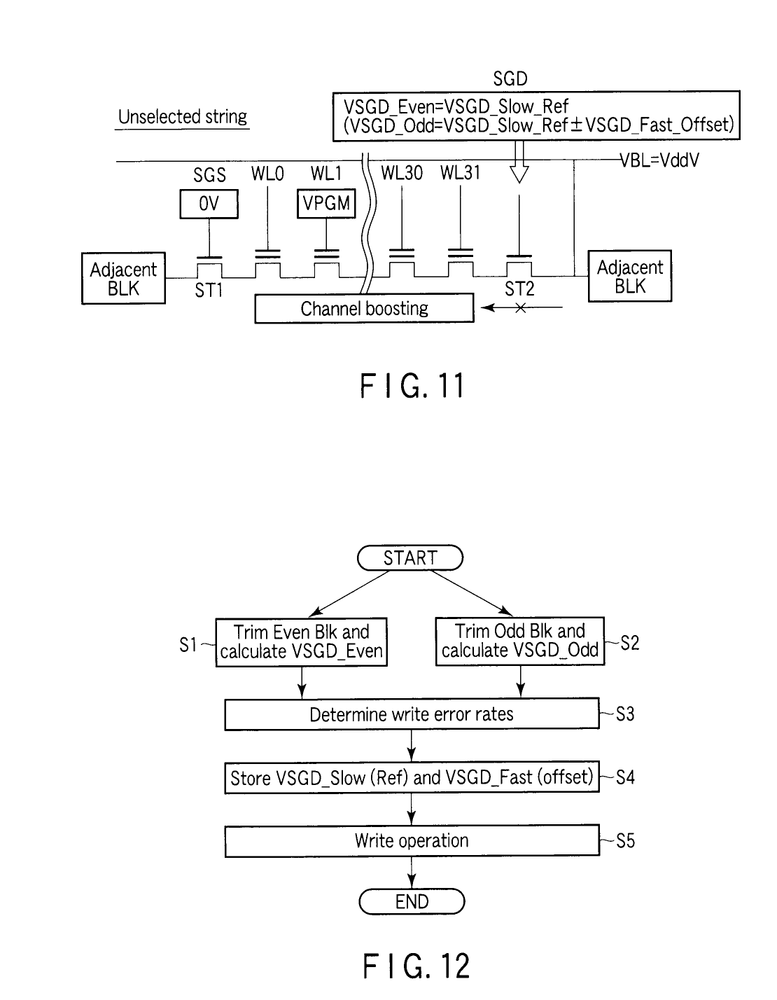

FIG. 11 shows the write operation of the NAND flash memory according to this embodiment.

In the write operation as shown in FIG. 11, Vdd is applied to a bit line BL in an unselected string. In addition, optimum voltages are applied to select transistors ST2 of a write error rate-slow block (Slow Blk) and a write error rate-fast block (Fast Blk), in order to cut off select transistors ST2. More specifically, an optimally trimmed select gate drain voltage VSGD_Even is applied to select transistor ST2 of the write error rate-slow block (Slow Blk) (in this embodiment, the even-numbered block [Even Blk]). On the other hand, a select gate drain voltage VSGD_Odd optimally regulated by using VSGD_Even as a reference is applied to select transistor ST2 of the write error rate-fast block (Fast Blk) (in this embodiment, the odd-numbered block [Odd Blk]). VSGD_Even and VSGD_Odd in this embodiment are indicated by

VSGD_Even=VSGD_Slow_Ref

VSGD_Odd=VSGD_Slow_Ref±VSGD_Fast_offset

The voltage data storage circuit 20 shown in FIG. 1 stores data (reference data) of select gate drain voltage VSGD_Slow_Ref, and data (offset data) of VSGD_Fast_offset.

FIG. 12 is a flowchart of trimming of the NAND flash memory according to this embodiment.

As shown in FIG. 12, in step S1, select gate drain voltage VSGD_Even is trimmed in the even-numbered block (Even Blk). Consequently, VSGD_Even optimum for the select transistor of the even-numbered block (Even Blk) is calculated.

On the other hand, in step S2, select gate drain voltage VSGD_Odd is trimmed in the odd-numbered block (Odd Blk). Consequently, VSGD_Odd optimum for the select transistor of the odd-numbered block (Odd Blk) is calculated.

For example, VSGD_Odd and voltage VSGD_Even is trimmed in the die-sort test.

Then, in step S3, the write error rates of the even-numbered block (Even Blk) and odd-numbered block (Odd Blk) are determined. More specifically, the rates at which write errors occur are determined by the trimming of the even-numbered block (Even Blk) and odd-numbered block (Odd Blk) in steps S1 and S2. For example, as shown in FIG. 10, voltage VSGD is raised during the trimming, and it is determined that a block in which the FBC rises fast (at a low voltage VSGD) is regarded as the write error rate-fast block (Fast Blk), and a block in which the FBC rises slowly (at a high voltage VSGD) is regarded as the write error rate-slow block (Slow Blk). Note that in this embodiment, the even-numbered block (Even Blk) is the write error rate-slow block (Slow Blk), and the odd-numbered block (Odd Blk) is the write error rate-fast block (Fast Blk).

Subsequently, in step S4, the voltage data storage circuit 20 stores, as reference data, data of select gate drain voltage VSGD_Even (VSGD_Slow Ref) optimum for the write error rate-slow block (Slow Blk) (in this embodiment, the even-numbered block [Even Blk]). This data (reference data) of voltage VSGD_Slow_Ref is, e.g., 4-bit data.

In addition, the voltage data storage circuit 20 stores, as offset data, data of a difference VSGD_Fast_offset between voltage VSGD_Even (VSGD_Slow_Ref) optimum for the write error rate-slow block (Slow Blk) and voltage VSGD_Odd optimum for the write error rate-fast block (Fast Blk) (in this embodiment, the odd-numbered block [Odd Blk]). This data (offset data) of voltage VSGD_Fast_offset is, e.g., 2-bit data.

After that, in step S5, the data (reference data) of voltage VSGD_Slow_Ref and the data (offset data) of VSGD_Fast_offset are read from the voltage data storage circuit 20. Thus, the write operation is performed by using select gate drain voltage VSGD_Even (VSGD_Slow_Ref) and VSGD_Odd (VSGD_Slow_Ref±VSGD_Fast_offset) respectively optimum for the even-numbered block (Even Blk) and odd-numbered block (Odd Blk).

### [Effects]

The above-mentioned third embodiment can achieve the same effect as that of the first embodiment.

In addition, in this embodiment, select gate drain voltage VSGD_Odd of the write error rate-fast block (Fast Blk) (in this embodiment, the odd-numbered block [Odd Blk]) is regulated by using select gate drain voltage VSGD_Even of the write error rate-slow block (Slow Blk) (in this embodiment, the even-numbered block [Even Blk]) as a reference. More specifically, the voltage data storage circuit 20 stores the data of select gate drain voltage VSGD_Slow_Ref of the write error rate-slow block (Slow Blk) as reference data, and the data of the difference VSGD_Fast_offset between VSGD_Even and VSGD_Odd as offset data. In the write operation, the state machine 8 reads the reference data and offset data, and controls the voltage to be applied to select gate SGD of each block. The reference data and offset data to be stored in the voltage data storage circuit 20 are respectively, e.g., 4-bit data and 2-bit data. When compared to the first embodiment, therefore, the number of bits of the data to be stored in the voltage data storage circuit 20 can be reduced. This makes it possible to reduce the circuit (chip) area.

Note that in this embodiment, the voltage data of the write error rate-slow block (Slow Blk) is used as the reference data. However, the present embodiment is not limited to this, and the voltage data of the write error rate-fast block (Fast Blk) may also be used as the reference data. More specifically, the voltage data storage circuit 20 can also store the data of select gate drain voltage VSGD_Odd (VSGD_Fast_Ref) of the write error rate-fast block (Fast Blk) as the reference data, and data of a difference VSGD_Slow_offset between VSGD_Even and VSGD_Odd as the offset data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a first block including a first select gate, and a first word line adjacent to one side of the first select gate;
a second block placed adjacent to the first block, and including a second select gate adjacent to the other side of the first select gate with a first contact line connected to a bit line being sandwiched therebetween, and a second word line adjacent to the second select gate and assigned the same number as that of the first word line;
a storage circuit stored first data concerning a voltage to be applied to the first select gate, and second data concerning a voltage to be applied to the second select gate; and
a controller configured to control the voltages to be applied to the first select gate and the second select gate,
wherein the controller applies, in a write operation, a first voltage to the first select gate based on the first data, and a second voltage different from the first voltage to the second select gate based on the second data.

2. The device of claim 1, wherein a width of the first word line differs from that of the second word line, and a width of the first select gate differs from that of the second select gate.

3. The device of claim 2, wherein
the first data is data of a voltage regulated in accordance with the widths of the first word line and the first select gate, and
the second data is data of a voltage regulated in accordance with the widths of the second word line and the second select gate.

4. The device of claim 2, wherein
the first data is data of a voltage regulated in accordance with the widths of the first word line and the first select gate,
the second data is data of a voltage regulated by using the first data as a reference, and
the number of bits of the second data is smaller than that of the first data.

5. The device of claim 4, wherein the number of bits of the second data is two, and that of the first data is four.

6. The device of claim 4, wherein the first data and the second data are determined based on a relationship between a failure bit count and the voltages to be applied to the first select gate and the second select gate.

7. The device of claim 6, wherein when the voltages to be applied to the first select gate and the second select gate are raised, the failure bit count in the first block increases faster than that in the second block.

8. The device of claim 1, wherein
the first block comprises NAND strings each including a first select transistor connected to the first select gate, and a first memory cell transistor connected to the first word line and having a current path connected in series with the first select gate transistor in a bit-line direction, and
the second block comprises NAND strings each including a second select transistor connected to the second select gate, and a second memory cell transistor connected to the second word line and having a current path connected in series with the second select gate transistor in a bit-line direction.

9. The device of claim 1, wherein the first block and the second block are mirror-symmetrically formed with the first contact line being sandwiched therebetween.

10. The device of claim 1, wherein the first block is an odd-numbered block, and the second block is an even-numbered block.

11. The device of claim 1, wherein
the first block includes a third select gate adjacent to a second contact line connected to a first source line, and a third word line adjacent to the third select gate,
the second block includes a fourth select gate adjacent to a third contact line connected to a second source line, and a fourth word line adjacent to the fourth select gate, and
the first select gate and the fourth select gate have equal widths, the first word line and the fourth word line have equal widths, the second select gate and the third select gate have equal widths, and the second word line and the third word line have equal widths.

12. The device of claim 1, wherein the first data and the second data are trimming information data.

13. A nonvolatile semiconductor memory device comprising:
a first block including a first select gate, and a first word line adjacent to one side of the first select gate;
a second block placed adjacent to the first block, and including a second select gate adjacent to the other side of the first select gate with a first contact line connected to a bit line being sandwiched therebetween, and a second word line adjacent to the second select gate and assigned the same number as that of the first word line; and
a controller configured to control the voltages to be applied to the first select gate and the second select gate,
wherein the controller applies, in a write operation, a first voltage to the first select gate, and a second voltage different from the first voltage to the second select gate.

14. The device of claim 13, wherein the first voltage and the second voltage are optimum for the first select transistor and the second select transistor, respectively.

15. The device of claim 13, wherein the first block and the second block are mirror-symmetrically formed with the first contact line being sandwiched therebetween.

16. The device of claim 13, further comprising, a storage circuit stored a first data and a second data
wherein the first voltage is based on the first data, and the second voltage is based on the second data.
